(19) United States
(12) Patent Application Publication
(10) Pub. No.: US 2006/0175703 A1
(43) Pub. Date: Aug. 10, 2006

(54) Thermally responsive pressure relief plug and method of making the same

(75) Inventors: Paul W. Godijn, Huizen (NL); Patrick Lusse, Delft (NL); Martinus N. Finke, De Meern (NL)

Correspondence Address: LOWRIE, LANDO & ANASTASI, RIVERFRONT OFFICE, ONE MAIN STREET, ELEVENTH FLOOR, CAMBRIDGE, MA, 02142, US

(73) Assignee: Fry's Metals, Inc., Jersey City, NJ (US)

(21) Appl. No.: 11/053,342

(22) Filed: Feb. 8, 2005

(51) Int. Cl. H01L 21/4763; H01L 23/48; H01L 23/52

(52) U.S. Cl. 257/741; 438/637

(57) ABSTRACT

A preformed pressure relief plug for insertion into a cavity of a vessel or valve. The plug may be formed of a eutectic alloy of bismuth, indium and tin.

### FIELD OF INVENTION

This invention relates generally to a thermally responsive pressure relief plug and method of forming same, and more particularly to a thermally responsive pressure relief plug and method for making same, the pressure relief plug being used in pressurized consumer packages.

### BACKGROUND

Internally pressurized vessels, such as tanks, valves, cylinders, etc. often require devices to prevent explosion at elevated temperatures. These devices typically respond to elevated temperature and/or pressure within the vessel to relieve the pressure within the vessel. For example, a pressure relief device may be a member that ruptures at a predetermined pressure. Alternatively, the pressure relief device may include a fusible alloy plug designed to melt at a predetermined temperature.

U.S. Pat. No. 5,435,333, to Duvall, discloses a thermally responsive pressure relief apparatus comprising a body and a plug. The plug is a hollow cylinder and includes a flange at one end of the cylinder and holes in the sidewall. The other end of the cylinder includes a rupturable section. The entire apparatus is threadably mounted in an opening in the vessel. A fusible bonding material is positioned between the outside wall of the plug and the cavity.

U.S. Pat. No. 6,006,774, to Lhymn et al., discloses a thermally activated pressure relief valve or fuse plug. The plug is formed of a fusible alloy matrix phase material and large reinforcing agents, such as fibers, spherical shots, particles, etc. The fusible alloy and large reinforcing agents are solidified in a plug cavity in a vessel. The plug cavity includes a nonslip surface designed so that the large reinforcing agents of the plug are supported by the textured surface of the cavity.

### SUMMARY OF INVENTION

In one embodiment, the present invention is directed to a thermally responsive pressure relief plug comprising a preformed solid body of fusible material, a first portion having a first cross sectional area, and a second portion having a second cross sectional area. The first cross sectional area is different from the second cross sectional area.

In a first aspect, the first cross sectional area is less than the second cross sectional area. In a second aspect, the second cross sectional area is designed to sealingly engage a valve seat. In a third aspect, the fusible material is an alloy. In another aspect, the alloy comprises a T_{M} range of between about 70° C. and about 100° C. In yet another aspect the alloy comprises a T_{M} range of between about 70° C. and about 85° C. In another aspect, the alloy comprises a metal selected from the group consisting of Bi, In, and combinations thereof. In one aspect, the alloy comprises a range of Bi between about 30 wt % and about 70 wt %. In yet another aspect, the alloy comprises a range of In between about 10 wt % and about 70 wt %. Another aspect is directed to the alloy further comprising Sb. In another aspect, the alloy comprises less than or equal to about 5 wt % Sb. Another aspect is directed to the alloy further comprising Cu. In another aspect, the alloy comprises less than or equal to about 5 wt % Cu. In yet another aspect, the alloy comprises about 34 wt % Bi and about 66 wt % In. Another aspect is directed to an alloy comprising about 17 wt % Sn, about 57 wt % Bi, and about 36 wt % In. Yet another aspect is directed to an alloy comprising about 16 wt % Sn, about 54 wt % Bi, and about 30 wt % In. In another aspect, the alloy further comprises a eutectic alloy. In another aspect, the eutectic point of the alloy ranges between about 70° C. and about 85° C. Another aspect is directed to an alloy having a eutectic point of about 72° C. Yet another aspect is directed to an alloy having a eutectic point of about 79° C., and yet another a eutectic point of about 81° C.

Another embodiment is directed to a thermally responsive pressure relief plug comprising a fusible material having a T_{M} range of between about 70° C. and about 85° C. In one aspect, the fusible material is a eutectic alloy. In a second aspect, the eutectic alloy has a eutectic point of about 72° C. In another aspect, the eutectic alloy has a eutectic point of about 79° C., and in another, about 81° C. In another aspect, the fusible material comprises Sn, Bi, and In.

Yet another embodiment is directed to a valve stem for an aerosol package comprising a valve stem body having a passageway, and a thermally responsive plug positioned within the passageway. The plug has a coefficient of thermal expansion substantially equal to a coefficient of thermal expansion of the valve stem body.

In one aspect, the valve further comprises a seal positioned between the body and the plug. In another aspect, the seal is an o-ring. In yet another aspect, the plug further comprises a first portion having a first cross sectional area, and a second portion having a second cross sectional area, wherein the first cross sectional area is different from the second cross sectional area. In another aspect, the first cross sectional area is less than the second cross sectional area. In another aspect, the o-ring 15′ is positioned between the second portion of the plug and an outer surface of the valve stem. Another aspect is directed to the plug comprised of fusible material, and yet another to a fusible material that is a eutectic alloy. In another embodiment, the alloy is selected from an alloy comprising Bi, In, and combinations thereof. In yet another aspect, the alloy further comprises Sn. In yet another embodiment, the alloy comprises a eutectic point of between about 70° C. and about 85° C.

Another embodiment is directed to a method of forming a thermally responsive plug comprising preparing an alloy, creating a sphere from the alloy, and shaping the sphere to form the plug. In a first aspect the alloy is a eutectic alloy. In a second aspect, shaping the alloy comprises cooling the alloy in a fluid. Another aspect is directed to cooling the alloy by dropping the alloy in a column of fluid. In another aspect, the fluid is oil. Another aspect is directed to sorting the shaped spheres according to diameter. In another aspect the spheres are pressed into a plug. In yet another embodiment, the eutectic alloy formed comprises Bin, In, and combinations thereof. In another embodiment, the alloy further comprises Sn.

Other advantages, novel features, and objects of the invention will become apparent from the following detailed description of non-limiting embodiments of the invention when considered in conjunction with the accompanying drawings, which are schematic and which are not intended to be drawn to scale. In the figures, each identical or nearly identical component that is illustrated in various figures typically is represented by a single numeral. For purposes of clarity, not every component is labeled in every figure, nor is every component of each embodiment of the invention shown where illustration is not necessary to allow those of ordinary skill in the art to understand the invention. In cases where the present specification and a document incorporated by reference include conflicting disclosure, the present specification shall control.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a cross sectional view of a plug according to one embodiment of the invention.

FIG. 2 is a cross sectional view of a plug according to another embodiment of the invention.

FIG. 3 is a cross sectional view of the plug of FIG. 2 positioned in a valve stem.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

A pressure relief plug for pressurized vessels may be formed of a thermally reactive material. As used herein, the term pressurized container includes any commercial or consumer package, such as a tank, a valve, and a canister having an internal pressure greater than atmospheric pressure and/or having the potential to develop an internal pressure greater than atmospheric pressure at a given temperature. For example, the container may, but need not, be pressurized at room temperature, but may exhibit an increase in pressure as temperature increases. Alternatively, the container may be under pressure at room temperature, such as gas cylinders and packaging for consumer products, including aerosol packages.

The pressure relief plug may be positioned anywhere within the container or the valve of the container, so long as the pressurized contents of the container may be released when the plug is exposed to elevated temperatures. For example, the pressure relief plug may be sealingly positioned in a wall or valve of the container. In a preferred embodiment, the pressure relief plug is positioned within a valve stem of the container. The pressure relief plug may have any size and shape suitable for a particular location of the container. For example, the pressure relief plug may be formed into wires, spheres, disks, collars, and the like. Upon exposure to elevated temperatures at which it is desirable to release the contents of the container, the pressure relief plug may rupture, melt, or otherwise be expelled from the container. In a preferred embodiment, the pressure relief plug melts, either entirely or in part, to allow a portion of the pressurized contents of the container to escape from the container until the pressure in the container reaches equilibrium with its surroundings.

The pressure relief plug may be formed of any fusible material having sufficient strength to withstand a selected range of internal pressures of a particular container and compatible with the particular container. The fusible material may be selected to melt at a predetermined temperature or within a predetermined temperature range. For example, the fusible material may be a thermoplastic resin or a metal, for example a metal alloy. The fusible material may have a melt temperature ranging between about 70° C. and about 100° C., preferable between about 70° C. and about 85° C.

In one embodiment, the fusible material has a coefficient of thermal expansion substantially equal to a coefficient of thermal expansion of the container, or of that portion of the container to which the plug forms a gas-tight seal. By preparing a plug having a coefficient of thermal expansion substantially equal to that of the container, the formation of leaks or even expulsion of the plug may be avoided over the usable temperature range of the container.

In one embodiment, the fusible material may be a metal alloy. The metal alloy may be bismuth-based, tin-based, indium-based, gallium-based, cadmium-based or lead-based. The alloy may be comprised of metals selected from the group consisting of: bismuth, tin, indium, copper, silver, gallium, antimony, lead, cadmium, mercury and combinations thereof. When selecting metals to create an alloy for plugs to be used in consumer products, it is oftentimes desirable to select lead-free, cadmium-free, mercury-free, and other environmentally friendly alloys in order to comply with applicable waste disposal regulations.

In another embodiment, the metal alloy may be a eutectic alloy, for example, an alloy of bismuth and indium or an alloy of bismuth, indium and tin. In one embodiment of the invention, the alloy comprises between about 30 wt % and about 70 wt % bismuth and between about 10 wt % and about 70 wt % indium. In one embodiment, the alloy comprises about 34 wt % bismuth and about 66 wt % indium, which has a eutectic point of about 72° C. In a preferred embodiment, the alloy may comprise tin, bismuth and indium. For example, the alloy may comprise between about 30 wt % and 70 wt % bismuth, between about 10 wt % and about 70 wt % indium, and less than about 25 wt % tin. In one embodiment, the alloy may comprise about 17 wt % tin, about 57 wt % bismuth and about 26 wt % indium with a eutectic point of about 79° C. In yet another embodiment, the alloy may comprise about 16 wt % tin, about 54 wt % bismuth, and about 30 wt % indium, with a eutectic point of about 81° C.

In another embodiment, the alloy may also comprise antimony and/or copper to adjust hardness. Antimony and/or copper may be added to the alloy to increase the hardness of the alloy. In one embodiment, the alloy comprises less than about 5 wt % of antimony. Alternatively, or in addition to the antimony, the alloy may comprise less than about 5 wt % copper. In one embodiment, the addition of either 2 wt % antimony or 2 wt % copper increased hardness by about 10%.

The pressure relief plug may be, but need not be, a solid body. In a preferred embodiment, the plug is solid. In another embodiment, the container comprises a valve formed of the fusible material, so that the valve also functions as the pressure relief plug.

The pressure relief plug may be preformed for insertion into an orifice of the container, and/or the valve within the container. For example, the pressure relief plug may comprise a first portion having a cross sectional area slightly smaller than a cross sectional area of an orifice to which it will be inserted. The plug may be press fitted within the orifice in such a manner that it may not be easily forced out of the container or valve by internal pressure of the material within the container under normal use. The pressure relief plug may also be attached to the container within the orifice. For example, the pressure relief plug may be soldered or glued to a wall of the container and/or positioned in the grommet of the container.

Examples of cross sectional shapes for the plug and corresponding orifice include, but are not limited to, cone, square, circle, oval, rectangle and triangle. Other cross-section shapes, such as, pentagon, hexagon, trapezoid, are all contemplated and are within the scope of this invention. The plug and corresponding orifice may also have a cross section of any pre-selected irregular shape.

The pressure relief plug may also comprise a second portion having a cross sectional area different from the cross sectional area of the first portion of the plug. In one embodiment, the cross sectional area of the second portion of the plug is less than the cross sectional area of the first portion of the plug, for complete insertion of the plug into the orifice. In another embodiment, the second portion of the plug has a cross sectional area greater than the cross sectional area of the orifice, so that the second portion is prevented from being inserted into the orifice. In this embodiment, the second, larger portion provides a larger heat sink area than a plug having only the first portion, and may enable a faster response to temperature increases. The second portion may also contact the surface of the container or valve seat of the orifice. The orifice and plug may be sized to provide sufficient release of the pressurized fluid when the internal pressure of the container increases with increasing temperature. The cross sectional shape of the first portion may, but need not, be the same as the cross sectional shape of the second portion of the plug.

Upon exposure to a predetermined temperature (typically greater than a normal operating temperature), at which it is desirable to release the contents of the container, the pressure relief plug may melt sufficiently to create an opening in the orifice in the container or valve within the container, thereby releasing the contents of the container. The plug may melt partially or entirely, and may be expelled from the container along with the contents of the container.

Sealing means may also be used to provide a gas-tight seal between the pressure relief plug and the orifice to which it is inserted. For example, a gas-tight seal may be formed of a sealing material, such as an adhesive, a gasket, or an o-ring, positioned between the pressure relief plug and the orifice. In addition to, or alternatively, the sealing material may be positioned between the pressure relief plug and a valve seat of the orifice. The sealing material may be formed of any material suitable for conditions of normal use of the container. The sealing material may be positioned within a groove formed in the plug and/or the orifice. In one embodiment, the sealing material is an o-ring positioned between an enlarged portion of the plug and a valve seat of the orifice.

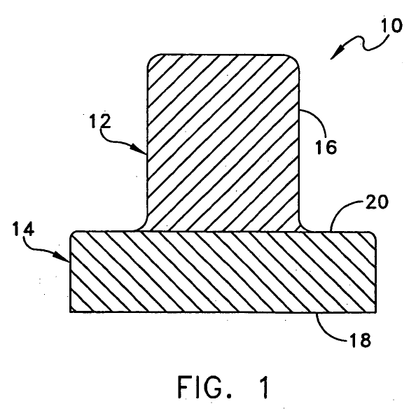

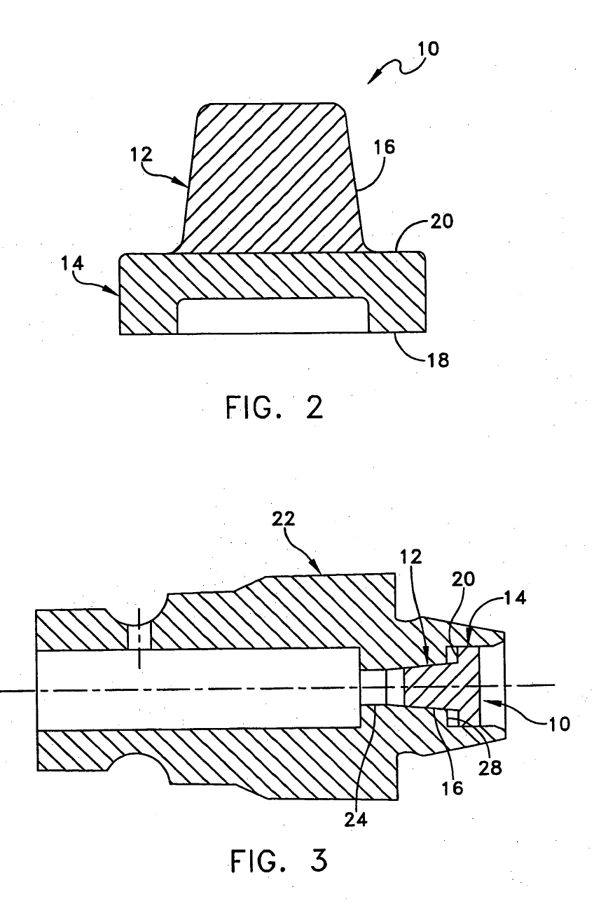

FIG. 1 shows one embodiment of a pressure relief plug 10 of the invention. Plug 10 includes a first portion 12 having a cross sectional area less than a cross sectional area of a second portion 14. As shown in FIG. 1, first portion 12 is cylindrical in shape for insertion into a corresponding cylindrical orifice. Sidewall 16 of the first portion 12 is shown to extend generally perpendicularly from the second portion 14, though other configurations are contemplated. As shown in FIG. 2, sidewall 16 of plug 10 may be tapered, or slightly angled, to form a cone for insertion into a correspondingly tapered or slightly angled orifice. As shown in FIGS. 1 and 2, the second portion 14 comprises a first surface 18 and a second surface 20. Second surface 20 may be constructed to abut a valve seat formed by an outer surface of the container or valve about a periphery of the orifice to prevent leakage of the contents of the container under normal use.

FIG. 3 shows the pressure relief plug 10 of FIG. 2, positioned within an orifice 24 of a valve stem 22. Tapered sidewall 16 of the first portion 12 is positioned adjacent inner surface 26 of orifice 24, and second surface 20 of the plug 10 is positioned adjacent a valve seat 28 of the valve stem 22. The second surface 20 of the plug 10 engages the valve seat 28 to seal the orifice and prevent release of the contents of the container through the orifice under normal conditions of use. A seal, such as an o-ring (not shown) may be positioned between sidewall 16 of the first portion 12 of plug 10 and inner surface 26 of the orifice 24, and/or between second surface 20 of the second portion 14 of plug 10 and the valve seat 28.

The alloy forming the plug 10 is selected so that the coefficient of thermal expansion of the alloy is substantially equal to the coefficient of thermal expansion of the valve stem, so that a friction fit between the valve stem 22 and the plug 10 remains substantially constant throughout a range of temperatures and pressures, until the plug melts from a temperature increase resulting in release of the pressurized contents of the container. Maintaining the friction fit between the plug and the orifice over a useable range of temperatures ensures that no gap or gaps develop between the plug and the orifice which may allow the contents of the container to escape at temperatures less than the temperature at which the plug is designed to release the contents of the container.

The pressure relief plug may be preformed into a desired shape by any conventional method, such as, for example, press forming a powder of an alloy, injection molding an alloy, and pouring a liquid plug shape. In a preferred embodiment, the pressure relief plug is created by forming a sphere from an alloy. The sphere is then press formed by a mold to form the shape of the plug.

In one embodiment, the alloy is heated to a temperature sufficient to remove dross residues, and then maintained at a temperature approximately 50° C. above the melting temperature of the alloy. The alloy is delivered to a second container, where the height of the alloy is accurately controlled in order to maintain the alloy at a substantially constant pressure for delivery to a nozzle. The alloy is allowed to drip through the nozzle and solidify in a column filled with oil, such as silicone oil, to form spheres. The spheres resulting from the drips of the alloy are collected and sorted by diameter, by conventional methods, such as moving the spheres through a sieve and moving the spheres between two rollers. The sieves may be selected to produce spheres having a desired size. The spheres are then press molded into the desired shape of the plug by means of a mold.

### EXAMPLE

In one embodiment, 16 wt % tin, 54 wt % bismuth, and 30 wt % indium are alloyed according to conventional methods. The alloy is heated to a temperature of about 150° C. to remove dross residues and maintained at a temperature of up to about 130° C. for delivery through a nozzle to a column filled with silicon oil The alloy is allowed to drip through the nozzle at a speed of about 5 to about 20 spheres per second. The spheres are collected and sorted to obtain a predetermined diameter of 1.71+/−0.02 mm. The entire sphere is press molded into the desired shape of the plug so that the variation in sphere diameter may be absorbed in a +/−0.1 mm overall height tolerance of the plug.

The first portion of the resultant plug has a diameter of about 1.1 mm+/−0.05 mm, and the second portion of the plug has a diameter about 2.0 mm+/−0.05 mm. The overall length of the plug, including the first and second portions, is about 1.7 mm+0, −0.2 mm wherein the height of the second portion is about 0.53 mm+/−0.02 mm.

The Sn₁₆Bi₅₄In₃₀ plug has a coefficient of thermal expansion in the range of about 25° C. to about 50° C. of about 7.0×10⁻⁵/° C. The plug is inserted into an orifice of a plastic valve stem having a coefficient of thermal expansion substantially equal to the coefficient of thermal expansion of the alloy. The coefficient of thermal expansion of the polymeric material used in the valve stem is about 1.1×10⁻⁴/° C.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A thermally responsive pressure relief plug comprising:
a preformed solid body fabricated from fusible material;
a first portion having a first cross sectional area; and
a second portion having a second cross sectional area;
wherein the first cross sectional area is different from the second cross sectional area.

2. The plug of claim 1, wherein the first cross sectional area is less than the second cross sectional area.

3. The plug of claim 2, wherein the second cross sectional area is designed to sealingly engage a valve seat.

4. The plug of claim 1, wherein the fusible material is an alloy.

5. The plug of claim 4, wherein the alloy comprises a T_{M} range of between about 70° C. and about 100° C.

6. The plug of claim 5, wherein the alloy comprises a T_{M} range of between about 70° C. and about 85° C.

7. The plug of claim 4, wherein the alloy comprises a metal selected from the group consisting of Bi, In, and combinations thereof.

8. The plug of claim 7, wherein the alloy comprises a range of Bi between about 30 wt % and about 70 wt %.

9. The plug of claim 8, wherein the alloy comprises a range of In between about 10 wt % and about 70 wt %.

10. The plug of claim 9, wherein the alloy further comprises Sb.

11. The plug of claim 10, wherein the alloy comprises less than or equal to about 5 wt % Sb.

12. The plug of claim 9, wherein the alloy further comprises Cu.

13. The plug of claim 12, wherein the alloy comprises less than or equal to about 5 wt % Cu.

14. The plug of claim 9, wherein the alloy comprises about 34 wt % Bi and about 66 wt % In.

15. The plug of claim 10, wherein the alloy comprises:
about 17 wt % Sn;
about 57 wt % Bi; and
about 26 wt % In.

16. The plug of claim 10, wherein the alloy comprises:
about 16 wt % Sn;
about 54 wt % Bi; and
about 30 wt % In.

17. The plug of claim 4, wherein the alloy further comprises a eutectic alloy.

18. The plug of claim 17, wherein the alloy comprises a eutectic point ranging between about 70° C. and about 85° C.

19. The plug of claim 18, wherein the eutectic point is about 72° C.

20. The plug of claim 18, wherein the eutectic point is about 79° C.

21. The plug of claim 18, wherein the eutectic point is about 81° C.

22. A thermally responsive pressure relief plug, comprising:
a fusible material comprising a T_{M} range of between about 70° C. and about 85° C.

23. The plug of claim 22, wherein the fusible material is a eutectic alloy.

24. The plug of claim 23, wherein the eutectic alloy has a eutectic point of about 72° C.

25. The plug of claim 23, wherein the eutectic alloy has a eutectic point of about 79° C.

26. The plug of claim 23, wherein the eutectic alloy has a eutectic point of about 81° C.

27. The plug of claim 23, wherein the fusible material comprises Sn, Bi, and In.

28. A valve stem for an aerosol package, comprising:
a valve stem body comprising a passageway; and
a thermally responsive plug positioned within the passageway;
wherein the plug has a coefficient of thermal expansion substantially equal to a coefficient of thermal expansion of the valve stem body.

29. The valve stem of claim 28, further comprising a seal positioned between the body and the plug.

30. The valve stem of claim 29, wherein the seal is an o-ring.

31. The valve stem of claim 29, wherein the plug further comprises:
a first portion having a first cross sectional area; and
a second portion having a second cross sectional area;
wherein the first cross sectional area is different from the second cross sectional area.

32. The valve stem of claim 31, wherein the first cross sectional area is less than the second cross sectional area.

33. The valve stem of claim 32, wherein the o-ring is positioned between the second portion of the plug and an outer surface of the valve stem.

34. The valve stem of claim 28, wherein the plug comprises a fusible material.

35. The valve stem of claim 34, wherein the fusible material is a eutectic alloy.

36. The valve stem of claim 35, wherein the alloy is selected from an alloy comprising Bi, In, and combinations thereof.

37. The valve stem of claim 36, wherein the alloy further comprises Sn.

38. The valve stem of claim 35, wherein the alloy comprises a eutectic point of between about 70° C. and about 85° C.

39. A method of forming a thermally responsive plug, comprising:
preparing an alloy;
creating a sphere from the alloy; and
shaping the sphere to form the plug.

40. The method of claim 39, wherein the alloy formed is a eutectic alloy.

41. The method of claim 39, wherein shaping the alloy comprises cooling the alloy in a fluid.

42. The method of claim 41, where cooling the alloy comprises dropping the alloy in a column of oil.

43. The method of claim 42, further comprising sorting the shaped spheres according to diameter.

44. The method of claim 43, wherein shaping the spheres comprises pressing the spheres into a plug.

45. The method of claim 40, wherein the eutectic alloy formed comprises Bi, In, and combinations thereof.

46. The method of claim 45, wherein the eutectic alloy formed further comprises Sn.
